(19) United States
(12) Patent Application Publication
(10) Pub. No.: US 2025/0033141 A1
(43) Pub. Date: Jan. 30, 2025

(54) APPARATUS FOR MASK-FREE MATERIAL DEPOSITION ON ARBITRARY SUBSTRATE BY DIRECT LASER WRITING AND METHOD FOR USING THE SAME

(71) Applicant: The Hong Kong University of Science and Technology, Hong Kong (CN)

(72) Inventors: Sen YANG, Hong Kong (CN); Zeying CHEN, Hong Kong (CN); Wing Ki LO, Hong Kong (CN)

(21) Appl. No.: 18/782,042

(22) Filed: Jul. 24, 2024

Related U.S. Application Data
(60) Provisional application No. 63/515,594, filed on Jul. 26, 2023.
(60) Provisional application No. 63/518,880, filed on Aug. 11, 2023.

(51) Int. Cl. B23K 26/03; B23K 26/06; B23K 26/14; B81C 1/00

(52) U.S. Cl. CPC B23K 26/032; B23K 26/0643; B23K 26/14; B81C 1/00444; B81C 2201/0102; B81C 2201/0176

(57) ABSTRACT

An apparatus includes an optical writing module and an optical characterization module. The optical writing module is configured to emit a laser beam and guide the laser beam toward a substrate. The optical characterization module is optically coupled with the optical writing module such that the optical writing module and the optical characterization module share the same optical path. The optical writing module is configured to emitting an observation light beam toward the substrate. The optical characterization module is further configured to determine whether a mixture of solution and suspension is in contact with the substrate. When the mixture is determined in contact with the substrate, the laser beam is enabled to irradiate the mixture near a surface of the substrate, so as to form a mechanically rigid material deposition in contact with the substrate.

### CROSS-REFERENCE TO RELATED APPLICATIONS

The present application claims priority from the U.S. provisional patent application Ser. No. 63/515,594 filed 26 Jul. 2023 and the U.S. provisional patent application Ser. No. 63/518,880 filed 11 Aug. 2023, and the disclosures of which are incorporated herein by reference in their entirety.

### TECHNICAL FIELD

The present invention generally relates to techniques for mask-free material deposition. More specifically, the present invention relates to an apparatus for mask-free material deposition on arbitrary substrate by direct laser writing and a method for using the same.

### BACKGROUND

Diamond and diamond-like substances possess numerous desirable properties, including wear resistance, thermal conductivity, electrical resistivity, acoustic transmission, and corrosion inertness, all of which make them highly attractive for various industrial applications. In quantum computing region, diamond works as a perfect carrier of qubits spin defect: nitrogen vacancy (NV) color centers. A kind of signal detection method requires micro waveguides deposited on the surface of diamond, and very close to NV centers. Tradition methods need expensive and complex equipment to grow conductive metal in specific location, and the alignment of waveguide with NV centers has always been a problem.

In addition, previous methods of material deposition usually require mask of pattern formation, which is not economical or timesaving. The waveguide design depends on the distribution of NV center in diamond, which is arbitrary and cannot be predicted. Therefore, each sample refers to a unique design, which makes the mask a disposable item, ridiculously. A mask-free method with low economic and time cost is in urgent need.

The attachment of micro material patterns on different substrate is very important in many aspects. Due to the cleaning process existence, sometimes people expect the deposited micro material patterns could survive after cleaning. Some existing method achieve this with heavy etching on the surface of the substrate, while this should be avoided in some cases. The harm to the surface may cause problems, and direct laser writing provides possible solution for overcome the mentioned problems.

Therefore, there is a need for an improved approach to material deposition on the surface of a substrate without using a mask, thereby removing limitations on the substrate material and potentially enhancing the adhesion of deposited patterns.

### SUMMARY OF INVENTION

It is an objective of the present invention to provide apparatuses and methods for using the same to address the aforementioned issues in the prior arts.

In the present invention, the provided solution relates to material deposition that are useful for the production of electrically conductive, semiconductive, insulative features and patterns. By the provided apparatus, the composition may advantageously be deposited on a variety of substrate at low temperatures. The deposited material forms strong attachment with the substrate and can resist flushes, ultrasound and the immerse of organic solvent. The nanoparticle composition allows deposition being formed without mask on different substrates.

In accordance with one aspect of the present invention, a method for using a platform for mask-free material deposition on arbitrary substrate is provided. The method includes steps as follows: holding a substrate using a substrate holder; providing a first solution comprising metalate, metal ions, reactive halogen ions, or combinations thereof onto the substrate using a first liquid injector; providing a first suspension comprising nanoparticles, a light sensitive reducing agent, an electron providing solvent, or combinations thereof onto the substrate using a second liquid injector, so as to form a reagent on the substrate with the substrate exposed to surrounding gas or an air environment; arranging a laser source for emitting a laser beam; guiding the laser beam and focusing the laser beam onto the reagent on the substrate; arranging a light source for emitting an observation light beam onto the reagent on the substrate; and determining whether the reagent is kept on a first region of the substrate, wherein, when the reagent is determined to be on the first region of the substrate, the laser beam is enabled to irradiate the reagent on the first region of the substrate, so as to form a mechanically rigid material deposition in contact with the first region of the substrate, and wherein the irradiation to the reagent by the laser beam occurs at the gas or the air environment.

In accordance with one aspect of the present invention, a method for using a platform for mask-free material deposition on arbitrary substrate is provided. The method includes steps as follows: holding a substrate using a substrate holder; providing a first solution comprising metalate, metal ions, reactive halogen ions, or combinations thereof into a transparent solution container using a first liquid injector; providing a first suspension comprising nanoparticles, a light sensitive reducing agent, an electron providing solvent, or combinations thereof into the transparent solution container using a second liquid injector, so as to form a mixture of the first solution and the first suspension in the transparent solution container; positioning a sample in the transparent solution container such that the sample is immersed in the mixture of the first solution and the first suspension; arranging a laser source for emitting a laser beam; guiding the laser beam and focusing the laser beam onto the sample; arranging a light source for emitting an observation light beam onto the sample; and enabling the laser beam to irradiate the sample, so as to form a mechanically rigid material deposition in contact with the sample.

In accordance with one aspect of the present invention, an apparatus for mask-free material deposition on arbitrary substrate is provided. The apparatus includes an optical writing module and an optical characterization module. The optical writing module is configured to emit a laser beam and guide the laser beam toward a substrate. The optical characterization module is optically coupled with the optical writing module such that the optical writing module and the optical characterization module share the same optical path. The optical characterization module is configured to emit an observation light beam toward the substrate. The optical characterization module is further configured to determine whether a mixture of solution and suspension is in contact with the substrate. When the mixture is determined in contact with the substrate, the laser beam is enabled to irradiate the mixture near a surface of the substrate, so as to form a mechanically rigid material deposition in contact with the substrate.

In the present disclosure, a conductive, semiconductive, or insulative material deposition method for fabricating functional patterns on arbitrary substrates is provided. The material deposition forms a strong attachment to the substrate, facilitated by direct-write laser advantageously. Additionally, the material deposition has a low conversion temperature, preventing damage to the substrates. The nanoparticle composition enables deposition to be formed without a mask on different substrates. Moreover, the solution provided by the present invention can achieve nitrogen vacancy (NV) optical detection and waveguide deposition in a single setup at the same time.

### BRIEF DESCRIPTION OF DRAWINGS

Embodiments of the invention are described in more details hereinafter with reference to the drawings, in which:

FIG. 1 is a schematic drawing for an apparatus for mask-free material deposition on arbitrary substrate according to some embodiments of the present disclosure;

FIG. 2A, FIG. 2B, FIG. 2C, and FIG. 2D show schematic drawings illustrating a method for using a platform for mask-free material deposition on arbitrary substrate according to one embodiment of the present invention;

FIG. 3 show a schematic drawing illustrating a method for using a platform for mask-free material deposition on arbitrary substrate according to one embodiment of the present invention; and

FIG. 4 is a schematic drawing for an apparatus for mask-free material deposition on arbitrary substrate according to some embodiments of the present disclosure.

### DETAILED DESCRIPTION OF THE INVENTION

In the following description, apparatuses for mask-free material deposition on arbitrary substrate and methods using the same as the platforms and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

In the present disclosure, various embodiments or examples illustrating different aspects of the subject matter are provided. It includes specific examples of components and arrangements. However, these descriptions are only illustrative and not meant to be restrictive. When describing features, mentioning that the first feature is formed on or above the second feature may refer to cases where the first feature directly contacts the second feature or where an additional feature separates them. Furthermore, reference numbers or letters may be repeated in examples for clarity and simplification, without implying a relationship between the different embodiments or configurations described.

In this context, to simplify explanations, terms related to spatial orientation such as “under”, “below”, “lower”, “above”, “upper”, “lower portion”, “left side”, “right side”, and similar expressions may be employed to illustrate the relationship between one component or feature and another component or feature depicted in the figures. Beyond the orientations depicted in the figures, these spatial terms are intended to encompass various orientations of the device during its use or operation. The device could be positioned differently (e.g., rotating the passivation layer by 90 degrees or in other orientations), and the spatial descriptors mentioned here may accordingly be applied for clarification. It's important to note that when a component is described as “connected” or “coupled” to another component, it could be directly connected to or coupled to that component, or there might be an intermediary component involved.

In the present disclosure, terms like “approximately”, “basically”, “substantially”, and “about” are used to describe slight variations. When combined with an event or circumstance, these terms may indicate both exact and approximate occurrences of the event or circumstance. When used concerning a specific value or range, “about” generally denotes within ±10%, ±5%, or ±1% of the given value or range. Unless stated otherwise, all ranges mentioned include their endpoints. For instance, “substantially coplanar” may denote surfaces positioned within a few micrometers (μm) of each other along the same plane, such as within 10 μm, 5 μm, or 1 μm.

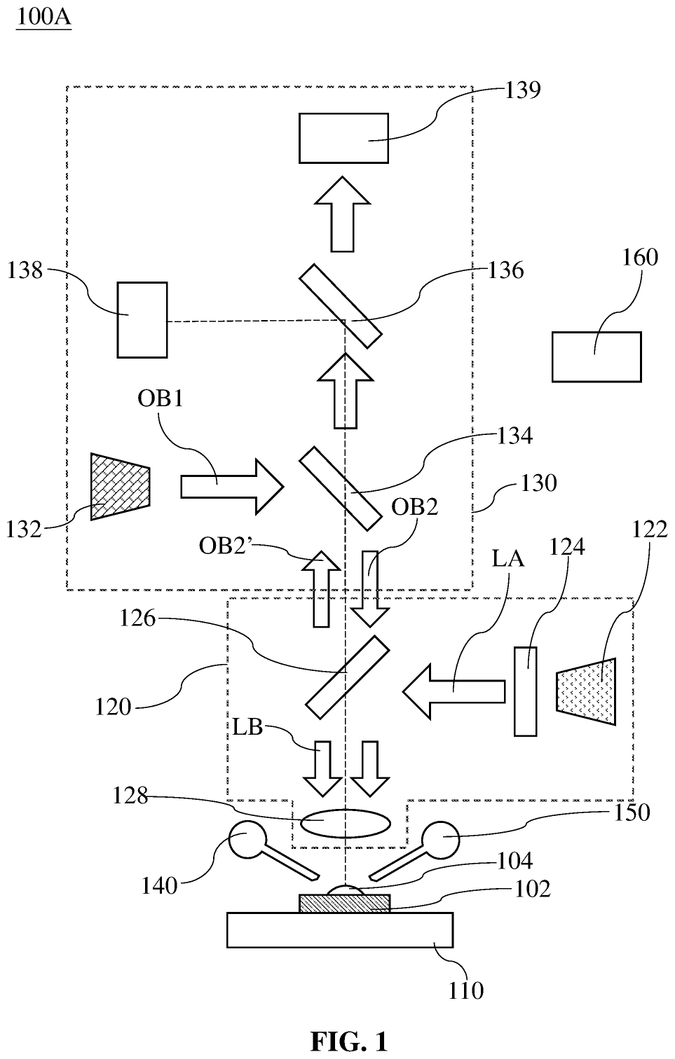

FIG. 1 is a schematic drawing for an apparatus 100A for mask-free material deposition on arbitrary substrate according to some embodiments of the present disclosure. The apparatus 100A serves as a platform for a direct laser writing system, providing a one-stop service. The apparatus 100A includes a sample holder 110, an optical writing module 120, an optical characterization module 130, a first liquid injector 140, a second liquid injector 150.

The sample holder 110 is configured to hold a substrate 102 or fix the substrate 102 to a top surface thereof. The substrate 120 is to be processed for formation of mechanically rigid material deposition on a top surface of the substrate 120. The formation of the mechanically rigid material deposition forms from a reagent 104. The reagent 104 is formed by mixing solution and suspension, which are respectively dropped or injected by the first liquid injector 140 and the second liquid injector 150. In various embodiments, before the formation of the mechanically rigid material deposition, the first liquid injector 140 and the second liquid injector 150 can be prepared well.

The first liquid injector 140 is configured to provide a first solution including metalate, metal ions, reactive halogen ions, or combinations thereof. In this regard, the first liquid injector 140 has an inner wall that is chemically inert with the stored first solution, preventing any chemical reactions from occurring, allowing them to be stably stored inside the first liquid injector 140. In one embodiment, the first solution includes Cl ions, F ions, OH ions, or combinations thereof. In one embodiment, the first solution includes gold(III) chloride hydrochloride (HAuCl₄), chloroplatinic acid (H₂PtCl₆), silver nitrate (AgNO₃), ferric chloride (FeCl₃), precious metal solution, or combinations thereof. The inner wall of the first liquid injector 140 is selected to prevent any chemical reactions from occurring among the stored substances. In some embodiment, the first liquid injector 140 can be configured to carry out drop-casting, spraying, microfluidic channels, ink injections, or combinations thereof, enabling the reagent 104 to be applied to the substrate 102 by optionally selecting drop-casting, spraying, microfluidic channels, ink injections, or combinations thereof.

The second liquid injector 150 is configured to provide a first suspension including nanoparticles, a light sensitive reducing agent, an electron providing solvent, or combinations thereof. In this regard, the second liquid injector 150 has an inner wall that is chemically inert with the stored first suspension, preventing any chemical reactions from occurring, allowing them to be stably stored inside the second liquid injector 150. In one embodiment, the light sensitive reducing agent of the first suspension includes reduced graphene oxide, quantum dots, carbon ink particles, or combinations thereof. In one embodiment, the electron providing solvent of the first suspension includes water, ethanol, propanol, isopropanol, acetone, methanol, or combinations thereof. The inner wall of the second liquid injector 150 is selected to prevent any chemical reactions from occurring among the stored substances. In some embodiment, the second liquid injector 150 can be configured to carry out drop-casting, spraying, microfluidic channels, ink injections, or combinations thereof, enabling the reagent 104 to be applied to the substrate 102 by optionally selecting drop-casting, spraying, microfluidic channels, ink injections, or combinations thereof.

It is noted that although both the first liquid injector 140 and the second liquid injector 150 are used for injection, according to various embodiments of the present invention, a single injector for injecting a mixture of the first solution and the first suspension is also available. The present invention is not limited by the form of the injection.

The optical writing module 120 is disposed over the sample holder 110 and includes a laser source 122, an optical modulation component 124, a dichroic mirror 126, and a lens 128.

The laser source 122 is optically coupled with the optical modulation component 124 and is configured to provide a laser beam LA. The laser source 122 can provide a continuous wave laser or a pulsed laser in a visible range or with 405 nm or 532 nm wavelength. Under the condition where the laser source 122 is configured to provide a laser beam with a wavelength of 405 nm or 532 nm, laser power is set to range from 0.01 mW to 400 mW. In one embodiment, the optical modulation component 124 is a shutter or an acousto-optic modulator (AOM) for controlling the on/off state of the laser beam LA. The laser source 122 of the present invention is not limited by the wavelength applied to the laser beam.

The dichroic mirror 126 is coupled with the laser source 122 to receive the laser beam LA. The dichroic mirror 126 is configured to reflect the laser beam LA, thereby changing its propagation direction, called a laser beam LB after the reflection at the dichroic mirror 126. In this regard, the dichroic mirror 126 is further configured to allow another light beam with a different wavelength than the laser beam LA to pass through. For example, an observation light beam originating from a position higher than the dichroic mirror 126 can pass through it and continue to propagate downward. As such, the laser beam and the observation light beam can be separated by using the dichroic mirror 126.

The lens 128 is coupled with the dichroic mirror 126 to receive the laser beam LB and acts as an objective to focus the laser beam LB onto the top surface of the substrate 102. For example, after being focused by the lens 128, the laser beam LB can be concentrated onto the reagent 104 on the substrate 102. In one embodiment, the lens 128 is arranged by using an air objective lens, an oil objective lens, or a water immersion objective lens.

One of the purposes of setting the optical writing module 120 is to guide a laser beam onto the reagent 104 on the substrate 102. In one embodiment, the optical writing module 120 further includes an optical coupler to receive the light beam LB from to the reagent 104 on the substrate 102. In one embodiment, the optical coupler is arranged by using at least one photonic waveguide, at least one optical fiber, at least one evanescent coupler, or combinations thereof. In one embodiment, the optical coupler is arranged by using reflector and lens in free space. In one embodiment, the optical writing module 120 further includes a laser galvo scanner system configured to control the focus movement of the lens 128. Accordingly, the optical writing module 120 can optically adjust the position of the focus of the laser beam LB onto the reagent 104 on the substrate 102 using the laser galvo scanner system. In this regard, the focus of the laser beam LB is adjusted to a position within the reagent 104 and near the surface of the substrate 102, including continuous movement along the surface direction of the substrate 102.

The optical characterization module 130 is disposed over the sample holder 110 and the optical writing module 120 and includes a light source 132, a first light splitter 134, a second light splitter 136, an optical receiver 138, and an image recorder 139. The optical characterization module 130 is optically coupled with the optical writing module 120 so they can share the same optical path.

The light source 132 is optically coupled with the first light splitter 134 and is configured to provide a light beam OB1. The light beam OB1 serve as an observation light beam for optical characterization which has a wavelength or a wavelength interval individually than that of the laser beam provided by the laser source 122.

The first light splitter 134 and the second first light splitter 136 are collectively configured to guide the observation light beam. They are optically coupled with the light source 132, the optical receiver 138, the image recorder 139, and the dichroic mirror 126. Specifically, the light beam OB1 is at least reflected by the first light splitter 134, referred to as a light beam OB2 then, and then it passes through the dichroic mirror 126 to be propagated toward the reagent 104 on the substrate 102 through the lens 128. In this regard, the observation light beam is utilized in the manufacturing process for enabling real-time observation via reflected light itself.

The reflection light to the light beam OB2 is labelled as the light beam OB2′, which is propagated to the first light splitter 134 and the second light splitter 136 in sequence. The first light splitter 134 and second light splitter 136 can guide the light beam OB2′ to the image recorder 139 configured to take real-time observation with respect to the formation of the mechanically rigid material deposition. In one embodiment, the image recorder 139 can determine whether the reagent 104 is kept on a desired region of the substrate 102. This can improve the platform's manufacturing yield of devices. The optical receiver 138 is configured to receive an optical signal from the reagent 104 on the substrate 102 for optical characterization without moving the substrate 102, including measurements of absorption coefficient, reflectivity, transmittance, or other optical properties.

In one embodiment, the apparatus 100A further includes an actuator 136 configured to adjust an optical relationship among the sample holder 110, the optical writing module 120, the optical characterization module 130, such that the focus of the laser source 122 can continuously moved along a surface of the substrate 102, resulting a horizontal shifting for a writing laser beam to the reagent 104 on the substrate 102. In this regard, the profile of the mechanically rigid material deposition depends on the trajectory of the writing laser beam.

The platform integrates components to enhance automation efficiency for direct laser writing systems, including automated tools for process control and detection. This design boosts productivity, reduces errors, and speeds up manufacturing processes for devices. Additionally, it allows for real-time imaging, observation, and recording and measurement of optical characteristics during the laser writing process.

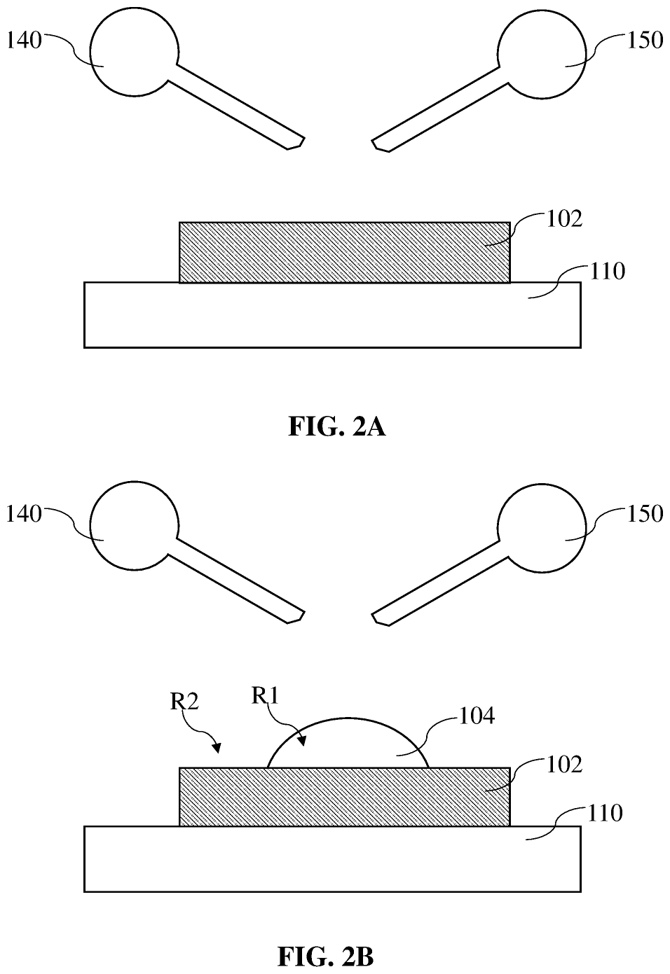

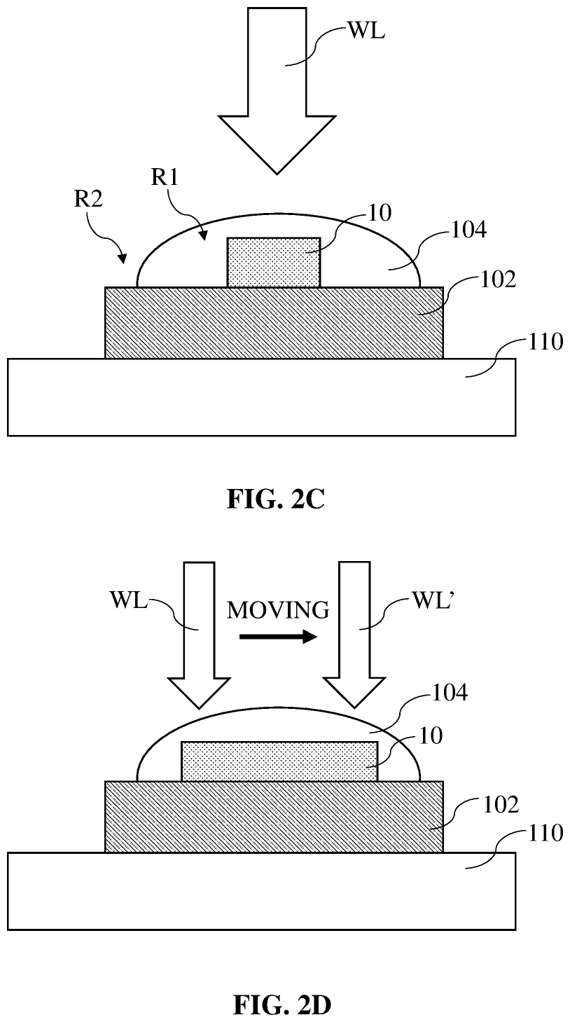

FIG. 2A, FIG. 2B, FIG. 2C, and FIG. 2D show schematic drawings illustrating a method for using a platform for mask-free material deposition on arbitrary substrate according to one embodiment of the present invention.

In FIG. 2A, a substrate 102 is held using the sample holder 110, facilitating the subsequent deposition process on the substrate 102. At this stage, preparatory work can also be performed. The first solution is well-done prepared and is placed into the first liquid injector 140, and the first suspension is well-done prepared and is placed into the second liquid injector 150. The optical writing module 120 is arranged such that the focal point of the laser source is adjusted to a position near the surface of the substrate 102, which is the area slated for deposition. The optical characterization module 130 is arranged such that the observation light beam provided by the optical characterization module 130 is ready to take images or videos for the deposition at the substrate 102.

In FIG. 2B, a reagent 104 is formed on the substrate 102. Specifically, a portion of the first solution and a portion of the first suspension are applied to a surface of the substrate 102 via the first liquid injector 140 and the second liquid injector 150, so as to mix them to form a reagent 104 on the substrate 102. In this stage, the substrate 102 is exposed to surrounding gas or an air environment. For example, a first region R1 of the substrate 102 is covered by the reagent 104 and a second region R2 of the substrate 102 is directly exposed to surrounding gas or an air environment.

Next, referring to FIG. 2C, it is to determine whether the reagent 104 is kept on the first region R1 of the substrate 102 using the image recorder 139 of the optical characterization module 130 (see FIG. 1). When the reagent 104 is determined to be on the first region R1 of the substrate 102, the laser source 122 and the optical modulation component 124 of the optical writing module 120 (see FIG. 1) are triggered such the a writing laser beam WL is enabled to irradiate the reagent 104 on the first region R1 of the substrate 102, so as to form a mechanically rigid material deposition 10 in contact with the first region R1 of the first substrate 102. The irradiation to the reagent 104 by the writing laser beam WL is mask-free such that the second region R2 of the substrate 102 is exposed to the gas or the air environment during the irradiation. The location of the formed mechanically rigid material deposition 10 is determined by a focal point of the laser source 122 of the optical writing module 120 (see FIG. 1). In one embodiment, after the deposition process for forming the mechanically rigid material deposition 10 once, the deposition process can be repeated to thicken or densify the mechanically rigid material deposition 10.

Briefly, after those prepared materials (e.g., metalate or metal ions, reactive halogen ion, and nanoparticles, light sensitive reducing agent, or electron providing solvent) are applied onto the surface of substrate 102, the writing laser beam WL with appropriate power is focused onto the substrate surface; thereafter, photon induced chemical reduction process completes, and the materials congregate into the mechanically rigid material deposition 10.

Specifically, when a writing laser beam WL is focused on the reagent 104, free electrons, excited from the valence band of the light-sensitive reducing agent like semiconductor nanoparticles by photons, initiate a chemical reduction process. This process converts metal ions present in the solution into metal particles, microcrystals of metal salt, or metal oxide particles on the surface of the substrate. As the initial material takes shape, the localized heating caused by the laser leads to increased vapor pressure, eventually resulting in the formation of microbubbles. These microbubbles contribute to convective flows and capillary forces, transporting particles towards the base of the microbubble where some become pinned. Simultaneously, the focused writing laser beam WL serves as an optical trap, driving particles towards the focal point on the substrate surface. The scattering force further enhances the adhesion between the particles and the substrate. By combining these mechanisms, the reduced material that grows on the particle's surface effectively acts as an adhesive, bonding the trapped particles together to form a mechanically sturdy deposition 10 on the substrate surface or on top of a previous layer of deposited material (for 3D-pattern). Additionally, the presence of reactive halogen ions reinforces the attachment between the material and the substrate. The in-situ etching mechanism, facilitated by the reactive halogen ions, simultaneously enhances the strong adhesion between the deposited material and the substrate. Furthermore, such the approach is free from any strong acid and thus allows less contamination of terminated surface of the substrate.

In some embodiment, the applied writing laser beam WL is with conditions as follows: Precision: about 100 nm; Laser Wavelength: about 532 nm; and Speed: 2 mm/s; Power: 0.01 mW-400 mW. The power of the writing laser beam WL can be kept low, 400 mW at maximum at any substrate. The power depends on the N.A. value of the objective. In contrast, common laser writing methods require a high-power ultrafast laser. By the approach above, the mechanically rigid material deposition 10 is deposited as a solid structure with functional patterns and remains strong adhesion to the substrate 102, allowing waveguide and device fabrication. For example, the mechanically rigid material deposition 10 is deposited as a solid metallic structure with strong adhesion to the substrate 102 that the deposition remain intact after being ultrasound for more than 30 minutes in different solvent, including acetone, iso-propanol or ethanol. In one embodiment, the mechanically rigid material deposition 10 is a solid and rigid composite pattern made of pure metal, solid metal salt, metal oxide or the combinations thereof.

Referring to FIG. 2D, by using a laser galvo scanner system or an actuator, an optical relationship among the sample holder 110, the optical writing module 120, the optical characterization module 130 (see FIG. 1) is adjusted, such that the focal point of the laser source 122 of the optical writing module 120 (see FIG. 1) is continuously moved along a surface of the substrate 102, thereby forming the mechanically rigid material deposition 10 as a continuously pattern. Accordingly, the writing laser beam WL laterally moves to get the positions the writing laser beam WL′. As such, by controlling the relative movement of the focal point of the laser source 122 of the optical writing module 120 (see FIG. 1) to sample (e.g., the mechanically rigid material deposition 10), continuous deposition of metal forms electrodes, waveguides, capacitors, conductive or insulative pads or other functional patterns.

Then, the laser writing process is repeated, and thorough cleaning of the sample is applied to finish the configuration. The method can deposit different kinds of materials to fabricate complicated structures of devices, such as FETs, capacitors, resistors, etc. The method can be used for creating micro waveguides on diamond, manufacturing electronics, fabricating flexible devices and/or quantum devices, and/or photonic structures, and/or electrodes for testing electronic properties of 2D materials, especially in a manner to print circuits with a printer.

By this approach, the applied deposition method can be combined with optical characterization of semiconductor samples, which allows sample selection, Raman measurement, device fabrication and optical quality inspection within same setup; for example, Raman measurement or optical quality inspection can be performed on the mechanically rigid material deposition 10 with the substrate 102 held by the sample holder 110. Similarly, as the applied deposition method can be combined with optical localization of nitrogen vacancy (NV) centers in diamond, it allows direct NV optical detection, device fabrication, and optical measurement within same setup at the same time without markers on diamond surface; for example, NV optical detection and optical measurement are performed on the mechanically rigid material deposition 10 with the substrate 102 held by the sample holder 110 and without markers on a diamond surface of the substrate.

In one embodiment, the writing laser beam WL can be replaced by an electron beam to enhance accuracy. In one embodiment, the deposition method can be repeated for different material deposition by changing the first solution or the first suspension, so another formed mechanically rigid material deposition will have different compositions.

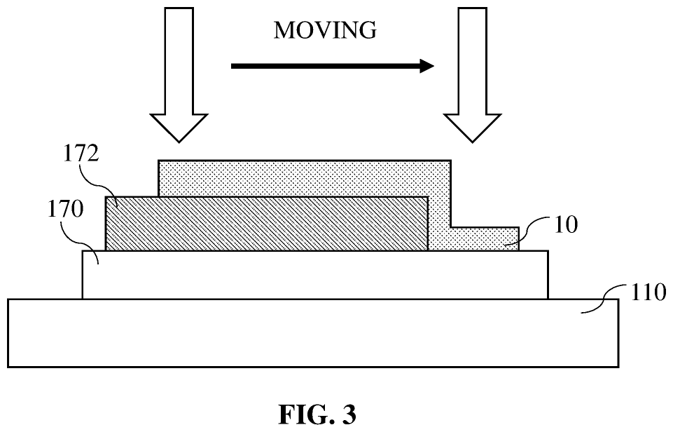

FIG. 3 show a schematic drawing illustrating a method for using a platform for mask-free material deposition on arbitrary substrate according to one embodiment of the present invention. In the present embodiment, the relative movement of the focal point of the laser source to sample is controlled such that the mechanically rigid material deposition 10 can be formed as a continuous deposition pattern across different substrates. Specifically, the sample holder 110 holds a bottom substrate 170, with a top substrate 172 attached to it. For example, the top substrate 172 grows from or is formed on the bottom substrate 170. During the deposition process for the mechanically rigid material deposition 10, the focal point of the laser source moves laterally from a position over the top substrate 172, then away from it. Consequently, the continuous deposition pattern of the mechanically rigid material deposition 10 extends from the top substrate 172 to a region of the bottom substrate 170, which is free from the coverage of the top substrate 172.

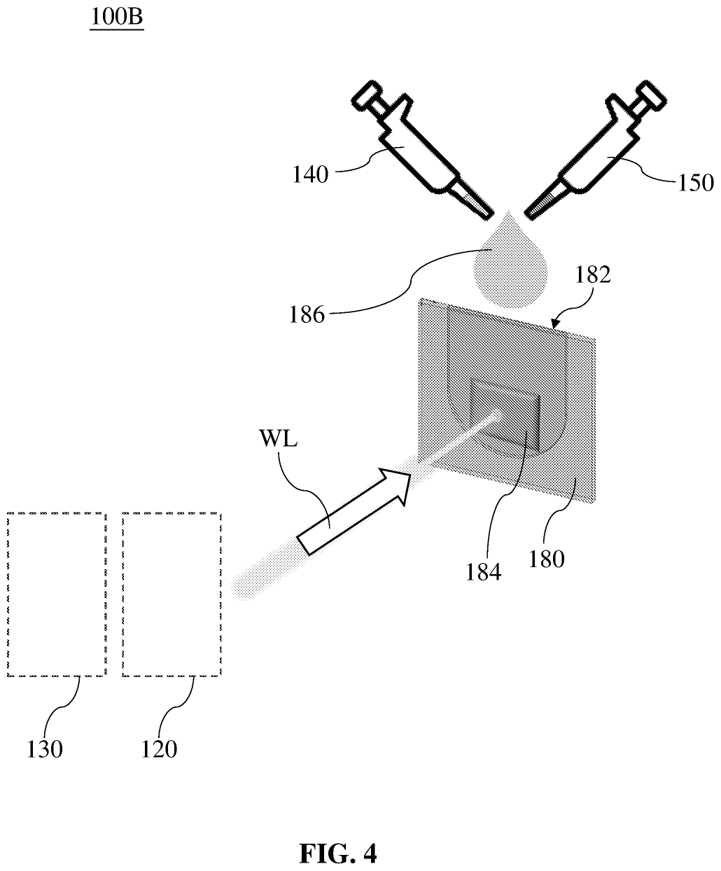

FIG. 4 is a schematic drawing for an apparatus 100B for mask-free material deposition on arbitrary substrate according to some embodiments of the present disclosure. The apparatus 100B has a configuration similar to that of the apparatus 100A, except the apparatus 100B further includes a transparent solution container 180 to replace the sample holder 110. The transparent solution container 180 has an opening 182 and an accommodation space in communication with the opening 182. The accommodation space can be configured to accommodate a sample 184 and a mixture 186 of the solution and the suspension from the first liquid injector 140 and the second liquid injector 150, respectively, the first liquid injector 140 and the second liquid injector 150 drop the solution and the suspension to fill the accommodation space up via the opening 182. The optical writing module 120 and the optical characterization module 130 are coupled with each other, so as to provide a writing laser beam WL propagated toward the sample 184 in the transparent solution container 180. During the formation of the mechanically rigid material deposition, an entirety of the sample 184 is immersed in the mixture 186. This configuration indicates that the technical solution provided by the present invention is flexible, and different parts can be replaced to adapt to different manufacturing conditions/requirements.

As discussed above, in the present disclosure, the mask-free material deposition on arbitrary substrate is achieved, in which the mask-free material deposition can be applied to various substrates, including but not limited to glass, quartz, sapphire, indium tin oxide, diamond, Si, SiC, silicon dioxide, polydimethylsiloxane, or combinations thereof. Further, in the present disclosure, there are advantages as follows:

(1). The solution provided by the present invention can be accomplished without mask (i.e. a mask-free process).

(2). The solution provided by the present invention can be accomplished at low temperature without harming the substrate beneath the deposited material.

(3). The solution provided by the present invention can achieve with sample selection, material deposition and sample quality inspection at the same time.

(4). The solution provided by the present invention can achieve ultra-high precision down to the order of tens of nanometer optically, based on the choose of wavelength of laser and the type of objective used.

(5). The solution provided by the present invention can deposited material under the beam spot immediately.

(6). The solution provided by the present invention can create 3D structure of the combination of materials.

(7). The solution provided by the present invention can complete the whole patterning process in seconds, for a single sample with the size of tens of micrometers.

(8). The solution provided by the present invention is superb in economy cost control and easy to promote.

(9). The solution provided by the present invention allows direct fabrication of fundamental micro electrical devices.

(10). The solution provided by the present invention can be deployed in trivial environment at room temperature, without extreme condition.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

1. A method for using a platform for mask-free material deposition on arbitrary substrate, comprising:
holding a substrate using a substrate holder;
providing a first solution comprising metalate, metal ions, reactive halogen ions, or combinations thereof onto the substrate using a first liquid injector;
providing a first suspension comprising nanoparticles, a light sensitive reducing agent, an electron providing solvent, or combinations thereof onto the substrate using a second liquid injector, so as to form a reagent on the substrate with the substrate exposed to surrounding gas or an air environment;
arranging a laser source for emitting a laser beam;
guiding the laser beam and focusing the laser beam onto the reagent on the substrate;
arranging a light source for emitting an observation light beam onto the reagent on the substrate; and
determining whether the reagent is kept on a first region of the substrate, wherein, when the reagent is determined to be on the first region of the substrate, the laser beam is enabled to irradiate the reagent on the first region of the substrate, so as to form a mechanically rigid material deposition in contact with the first region of the substrate, and wherein the irradiation to the reagent by the laser beam occurs at the gas or the air environment.

2. The method according to claim 1, further comprising:
taking real-time observation and recording with respect to the formation of the mechanically rigid material deposition via the observation light beam using an image recorder.

3. The method according to claim 2, further comprising:
receiving an optical signal, by an optical receiver, from the reagent on the substrate for optical characterization after the formation of the mechanically rigid material deposition without moving the substrate.

4. The method according to claim 2, wherein the laser source provides the laser beam with 405 nm or 532 nm wavelength at laser power ranging from 0.01 mW to 400 mW.

5. The method according to claim 2, wherein the light source provides the observation light beam has a wavelength or a wavelength interval individual than that of the laser beam.

6. The method according to claim 1, further comprising:
adjusting, during the formation of the mechanically rigid material deposition, an optical relationship between the laser beam and the reagent kept on the substrate, so as to form the mechanically rigid material deposition as a continuously pattern.

7. The method according to claim 1, further comprising guiding the laser beam using a dichroic mirror.

8. The method according to claim 1, further comprising separating the laser beam and the observation light beam using the dichroic mirror.

9. The method according to claim 1, further comprising controlling an optical modulation component for controlling an on/off state of the laser beam provided by the laser source.

10. The method according to claim 1, wherein the providing the first solution or the providing the first suspension is achieved by drop-casting, by spin-coating, by spraying, by microfluidic channels, by ink injections, or combinations thereof.

11. The method according to claim 1, wherein the irradiation to the reagent by the laser beam is mask-free such that a second region of the substrate is exposed to the gas or the air environment during the irradiation.

12. The method according to claim 1, further comprising performing Raman measurement or optical quality inspection on the mechanically rigid material deposition without moving the substrate after the formation of the mechanically rigid material deposition.

13. The method according to claim 1, wherein the first solution comprises Cl ions, F ions, OH ions, or combinations thereof.

14. The method according to claim 1, wherein the first solution comprises gold(III) chloride hydrochloride (HAuCl₄), chloroplatinic acid (H₂PtCl₆), silver nitrate (AgNO₃), ferric chloride (FeCl₃), precious metal solution, or combinations thereof.

15. The method according to claim 1, wherein the electron providing solvent comprises water, ethanol, propanol, isopropanol, acetone, methanol, or combinations thereof.

16. The method according to claim 1, wherein the light sensitive reducing agent comprises reduced graphene oxide, quantum dots, carbon ink particles, or combinations thereof.

17. The method according to claim 1, further comprising performing nitrogen vacancy (NV) optical detection and optical measurement on the mechanically rigid material deposition with the substrate held by the substrate holder and without markers on a diamond surface of the substrate.

18. A method for using a platform for mask-free material deposition on arbitrary substrate, comprising:
holding a substrate using a substrate holder;
providing a first solution comprising metalate, metal ions, reactive halogen ions, or combinations thereof into a transparent solution container using a first liquid injector;
providing a first suspension comprising nanoparticles, a light sensitive reducing agent, an electron providing solvent, or combinations thereof into the transparent solution container using a second liquid injector, so as to form a mixture of the first solution and the first suspension in the transparent solution container;
positioning a sample in the transparent solution container such that the sample is immersed in the mixture of the first solution and the first suspension;
arranging a laser source for emitting a laser beam;
guiding the laser beam and focusing the laser beam onto the sample;
arranging a light source for emitting an observation light beam onto the sample; and
enabling the laser beam to irradiate the sample, so as to form a mechanically rigid material deposition in contact with the sample.

19. An apparatus for mask-free material deposition on arbitrary substrate, comprising:
an optical writing module configured to emit a laser beam and guide the laser beam toward a substrate; and
an optical characterization module optically coupled with the optical writing module such that the optical writing module and the optical characterization module share the same optical path, wherein the optical characterization module is configured to emit an observation light beam toward the substrate;
wherein the optical characterization module is further configured to determine whether a mixture of solution and suspension is in contact with the substrate, and, when the mixture is determined in contact with the substrate, the laser beam is enabled to irradiate the mixture near a surface of the substrate, so as to form a mechanically rigid material deposition in contact with the substrate.

20. The apparatus according to claim 19, further comprising:
a first liquid injector configured to provide a first solution comprising metalate, metal ions, reactive halogen ions, or combinations thereof in contact with the substrate; and
a second liquid injector configured to provide g a first suspension comprising nanoparticles, a light sensitive reducing agent, an electron providing solvent, or combinations thereof in contact with the substrate.
